(19) United States
(12) Patent Application Publication
(10) Pub. No.: US 2025/0257992 A1
(43) Pub. Date: Aug. 14, 2025

(54) METROLOGY MEASUREMENTS ON SMALL TARGETS WITH CONTROL OF ZERO-ORDER SIDE LOBES

(71) Applicant: KLA Corporation, Milpitas, CA (US)

(72) Inventors: Vladimir Levinski, Migdal HaEmek (IL); Nireekshan K. Reddy, Tel Aviv (IL); Andrew V. Hill, Berkley, CA (US); David Koprivica, Petah Tikva (RS); Oren Lahav, Adi (IL); Daria Negri, Nesher (IL); Yonatan Vaknin, Yoqneam Illit (IL)

(21) Appl. No.: 18/796,860

(22) Filed: Aug. 7, 2024

Related U.S. Application Data
(60) Provisional application No. 63/553,137, filed on Feb. 14, 2024.

(51) Int. Cl. G01B 11/27; G03F 7/00

(52) U.S. Cl. CPC G01B 11/272; G03F 7/70633; G03F 7/706837; G03F 7/706851

(57) ABSTRACT

An optical metrology system may include illumination optics to direct pairs of mutually-coherent illumination beams to an optical metrology target, where the optical metrology target includes sets of periodic features having features with periodicity along different measurement directions. A pair of mutually-coherent illumination beams has opposing azimuth incidence angles and a common altitude incidence angle, where the azimuth incidence angles are rotated with respect to the measurement directions. The system may further generate dark-field images of the optical metrology target, where an image of a periodic structures is formed as a sinusoidal interference pattern generated by interference of a single non-zero diffraction order of light from each of the illumination beams within a pair of mutually-coherent illumination beams. A controller may generate optical metrology measurements along the measurement directions based on the images. The system may mitigate an impact of zero-order side lobes through blocking or image filtering.

### CROSS-REFERENCE TO RELATED APPLICATION

The present application claims the benefit under 35 U.S.C. § 119 (e) of U.S. Provisional Application Ser. No. 63/553,137, filed Feb. 14, 2024, entitled OVERLAY MEASUREMENT ON SMALL TARGETS, naming Vladimir Levinskim Nireekshan Reddy, Andrew Hill, David Koprivica, Oren Lahav, Daria Negri, and Yonatan Vaknin as inventors, which is incorporated herein by reference in the entirety.

### TECHNICAL FIELD

The present disclosure relates generally to optical metrology and, more particularly, to dark-field imaging optical metrology with mutually-coherent oblique illumination and control of zero-order side lobes.

### BACKGROUND

It is generally desirable to minimize the size of an optical metrology targets (e.g., overlay metrology targets, scanner acquisition targets, or the like) in order to maximize the area on a sample available for creating devices. In the case of a target design incorporating periodic features, reducing the optical metrology target size generally requires reducing the pitch of the periodic features, minimizing interactions between neighboring target cells, and/or minimizing the influence of features in the periphery of the target. However, the presence of zero-order side lobes (e.g., side lobes associated with zero-order diffraction) may negatively impact an optical metrology measurement, particularly as the optical metrology target size is reduced. Accordingly, it is desirable to develop systems and methods to address these deficiencies.

### SUMMARY

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1A is a conceptual view of an optical metrology system, in accordance with one or more embodiments of the present disclosure.

FIG. 1B is a simplified schematic view of an optical metrology sub-system suitable for illuminating an optical metrology target with one or more pairs of mutually-coherent illumination beams and imaging the optical metrology target based on a single non-zero diffraction order from each illumination beam, in accordance with one or more embodiments of the present disclosure.

FIG. 2 illustrates a conceptual diagram of illuminating an optical metrology target with a pair of mutually-coherent illumination beams, in accordance with one or more embodiments of the present disclosure.

FIG. 3 illustrates a top view of an advanced imaging metrology (AIM) optical metrology target, in accordance with one or more embodiments of the present disclosure.

FIG. 4 illustrates a conceptual schematic illustrating the collection of a single non-zero diffraction order from an AIM optical metrology target, in accordance with one or more embodiments of the present disclosure.

FIG. 5A illustrates a top view of a robust AIM (r-AIM) optical metrology target, in accordance with one or more embodiments of the present disclosure.

FIG. 5B illustrates a side view of two adjacent cells including Moiré structures that may form a quadrant of an r-AIM optical metrology target as depicted in FIG. 5A, in accordance with one or more embodiments of the present disclosure.

FIG. 6 illustrates a conceptual schematic illustrating the collection of a single non-zero diffraction order from an r-AIM optical metrology target, in accordance with one or more embodiments of the present disclosure.

FIG. 7A illustrates an image of a collection pupil of an optical metrology sub-system associated with imaging an optical metrology target using a mutually-coherent pair of illumination beams with azimuth angles aligned with a direction of periodicity of features on the optical metrology target, in accordance with one or more embodiments of the present disclosure.

FIG. 7B illustrates a simplified schematic of the collection pupil associated with FIG. 7A, in accordance with one or more embodiments of the present disclosure.

FIG. 8A illustrates an image of a collection pupil of an optical metrology sub-system associated with imaging an optical metrology target using a mutually-coherent pair of illumination beams with azimuth angles rotated with respect to a direction of periodicity of features on the optical metrology target, in accordance with one or more embodiments of the present disclosure.

FIG. 8B illustrates a simplified schematic of the collection pupil associated with FIG. 8A, in accordance with one or more embodiments of the present disclosure.

FIG. 8C illustrates an image of an optical metrology target 104 generated with a rotated pair of illumination beams 108 as shown in FIGS. 8A-8B, in accordance with one or more embodiments of the present disclosure.

FIG. 9 illustrates a simplified schematic of a collection pupil of an optical metrology sub-system having features with periodicity along both the X and Y directions imaged with two pairs of mutually-coherent illumination beams, in accordance with one or more embodiments of the present disclosure.

FIG. 10 illustrates a pupil image of an optical metrology sub-system depicting localized blocking of zero-order side lobes associated with the collection pupil configuration of FIG. 9, in accordance with one or more embodiments of the present disclosure.

FIG. 11 illustrates a flow diagram illustrating steps performed in a method 1100 for optical metrology with mutually-coherent illumination beams 108, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods for optical metrology with pairs of mutually-coherent illumination beams (e.g., mutually-coherent illumination beam pairs) oriented with common polar incidence angles and opposing azimuth incidence angles, where zero-order side lobes are controlled to reduce or eliminate an impact on a measurement. In particular, optical metrology along a particular measurement direction may be performed based on imaging an overlay target based on interference of a single non-zero diffraction order from each illumination beam in a mutually-coherent pair and zero-order side lobes associated with zero-order light is blocked and/or algorithmically filtered from an image.

As used herein, light associated with a particular diffraction order from an optical metrology target having periodic features may be characterized as having a pole (e.g., a central peak) and potentially side lobes. For example, side lobes may be associated with diffraction effects from edges or other features of the optical metrology target (or constituent cells therein) having different spatial frequencies than the periodic features and are primarily due to a finite extent of a grating within the overlay target (e.g., a finite cell size).

In particular, embodiments of the present disclosure are directed to illuminating an optical metrology target with a pair of mutually-coherent illumination beams at symmetric azimuth angles for each measurement direction of interest. As used herein, a pair of mutually-coherent illumination beams includes a pair of illumination beams that are both temporally and spatially coherent with respect to each other. However, each illumination beam need not necessarily be individually spatially coherent. In other words, the illumination beams in a mutually-coherent pair may be individually spatially incoherent across respective beam profiles, but light at azimuthally opposing points at common polar incidence angles is mutually temporally coherent.

An optical metrology measurement for a single measurement direction may utilize one pair of mutually-coherent illumination beams, while an optical metrology measurement for two measurement directions (e.g., two orthogonal measurement directions) may utilize two pairs of mutually-coherent illumination beams. Further, although illumination beams within each pair are mutually coherent, it is not necessary for beams in different pairs to be mutually coherent. Rather, it may be beneficial but not required that the pairs of illumination beams are incoherent with respect to each other.

Optical metrology with mutually coherent illumination beams is described generally in U.S. Pat. No. 12,032,300 titled IMAGING OVERLAY WITH MUTUALLY COHERENT OBLIQUE ILLUMINATION issued on Jul. 9, 2024, which is incorporated herein by reference in its entirety. However, it is contemplated herein that the presence of zero-order side lobes (e.g., side lobes associated with zero-order diffraction that may surround a zero-order pole) may negatively impact an optical metrology measurement generated using such a technique and further contemplated herein that the impacts of the zero-order side lobes may increase as a size of an optical metrology target is reduced.

Embodiments of the present disclosure are directed to various techniques to mitigate, reduce, or eliminate the impact of zero-order side lobes associated with an optical metrology measurement based on mutually-coherent oblique illumination. The systems and methods disclosed herein may be suitable for any type of optical metrology measurement based on periodic targets such as, but not limited to, overlay metrology or scanner acquisition (e.g., scanner alignment). In this way, an overlay metrology target may correspond to an overlay metrology target, a scanner acquisition target (e.g., an alignment target), or any other type of target.

In some embodiments, a pair of mutually-coherent illumination beams used to generate measurements for a particular measurement direction are azimuthally rotated relative to a direction of periodicity associated with the particular measurement direction. For example, an optical metrology target may include one or more cells designed for measurement along a particular measurement direction (e.g., an X direction) that include features with periodicity along the particular measurement direction. In some embodiments, a pair of mutually-coherent illumination beams used to illuminate the target is rotated relative to the particular measurement direction.

In this configuration, an optical metrology sub-system may provide a dark-field image since zero-order diffraction of the illumination beams does not contribute to image formation. Further, since each pair of illumination beams is mutually coherent, the single diffraction lobe associated with each illumination beam in the pair interfere to form a sinusoidal interference pattern in the image (e.g., a pattern of sinusoidal interference fringes). In particular, the periodicity of sinusoidal interference does not correspond to a periodicity of features on the overlay target, but rather will be dependent on multiple factors including, but not limited to, a pitch of grating structures in the optical metrology target, wavelength of the illumination beams, polar incidence angle of the illumination beams, and the azimuthal incidence angle (e.g., a difference between the azimuth incidence angle of the illumination beams relative to a characterized direction of periodicity). As a result, the various grating structures in the optical metrology target may be imaged with high contrast as pure sinusoids such that optical metrology measurements may be generated based on comparisons of relative phases of the neighboring cell images in accordance with a metrology recipe.

Further, this configuration may allow for the control of the impact of zero-order side lobes using various techniques. For example, this configuration may result in fringes associated with interference between the zero-order side lobes and first-order diffraction oriented along different directions compared to fringes associated with interference between first-order diffraction of different illumination beams, which may allow for algorithmic isolation and filtering of the impact of the zero-order side lobes. As another example, this configuration may separate zero-order side lobes from first-order diffraction in a collection pupil plane, which may enable physical blocking of at least a portion of the zero-order side lobes in the collection pupil. Further, both physical blocking and algorithmic filtering techniques may be combined.

In some embodiments, two pairs of mutually-coherent illumination beams are used to generate measurements along two measurement directions (e.g., orthogonal X and Y measurement directions). In this configuration, each pair of mutually-coherent illumination beams is rotated relative to the associated measurement direction (or both measurement directions) to provide for the mitigation of the impact of the zero-order side lobes on the measurements.

Further, in some embodiments, the pairs of mutually-coherent illumination beams are rotated to be in common quadrants an illumination pupil. Put another way, an angular separation between pairs of mutually-coherent illumination beams may be less than 45 degrees. Such a configuration may beneficially constrain zero-order side lobes to opposing quadrants in a collection pupil plane relative to first-order diffraction, which may enable convenient blocking of the zero-order side lobes in the collection pupil plane.

It is contemplated herein that various optical metrology target designs are suitable for optical metrology measurements with mutually-coherent illumination beam pairs. In some embodiments, an optical metrology target is an advanced imaging metrology (AIM) target. In this configuration, each cell of the optical metrology target may include grating structures from different lithographic exposures in non-overlapping regions on one or more layers, where the grating structures from the different lithographic exposures have the same pitch. In some embodiments, an optical metrology target is a Moiré target. In this configuration, each cell may include grating structures from different lithographic exposures in overlapping regions on two layers to form grating-over-grating structures or Moiré structures, where the grating structures from the different lithographic exposures have different pitches. Further, a cell may include a pair of Moiré structures in which the pitches on the constituent layers are reversed relative to each other. For example, a first Moiré structure may have a first pitch (P) on a first layer and a second pitch (Q) on a second layer, while a second Moiré structure may have the first pitch (P) on the second layer and the second pitch (Q) on the first layer. Such an optical metrology target may be referred to as a robust AIM (r-AIM) optical metrology target and provides that an optical metrology measurement may be determined based on relative phases between the two Moiré structures.

It is further contemplated herein that the intensity of zero-order side lobes may increase as a size of an optical metrology target decreases. In this way, mitigation of the impacts of zero-order side lobes using the systems and methods disclosed herein may enable the shrinking of optical metrology targets without sacrificing performance. In some cases, the systems and methods disclosed herein may enable a size reduction of optical metrology target size (e.g., a length of a side of an optical metrology target) to 20 micrometers, 8 micrometers, or less.

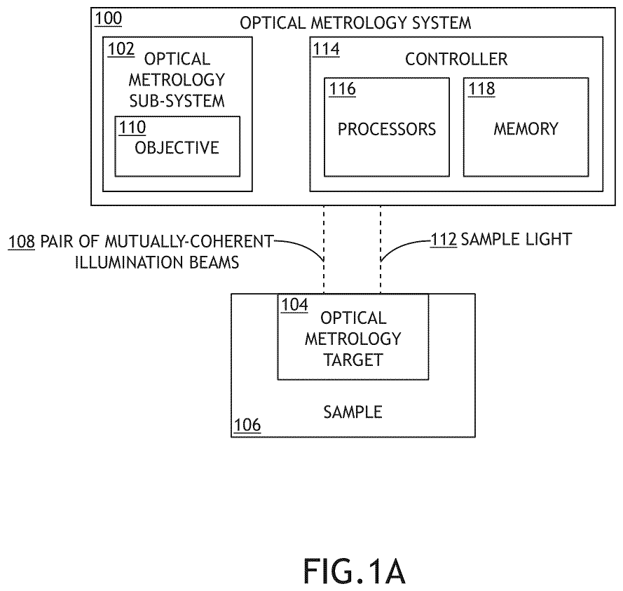

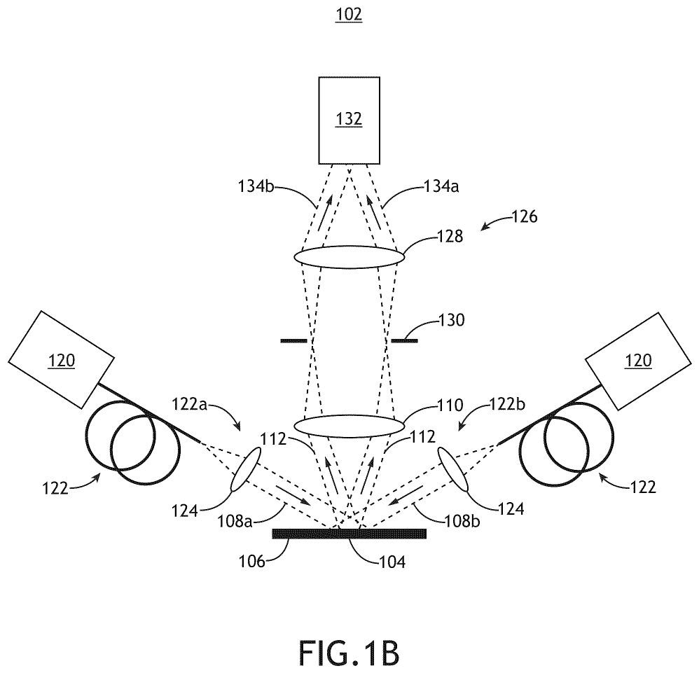

Referring now to FIGS. 1A-11, systems and methods for optical metrology based on mutually-coherent illumination beam pairs are described in greater detail, in accordance with one or more embodiments of the present disclosure.

FIG. 1A illustrates a conceptual view of an optical metrology system 100, in accordance with one or more embodiments of the present disclosure.

In some embodiments, the optical metrology system 100 includes an optical metrology sub-system 102 configured to image an optical metrology target 104 on a sample 106 based on illumination of the optical metrology target 104 with a pair of mutually-coherent illumination beams 108 per measurement direction of interest. In particular, each of the illumination beams 108a,b may fully illuminate the entirety of an optical metrology target 104. In this way, each cell of the optical metrology target 104 receives common illumination conditions to promote matched image brightness for all of the cells. The optical metrology sub-system 102 may then include an objective lens 110 to collect light from the optical metrology target 104, which is referred to herein as sample light 112. At least a portion of this sample light 112 may then be used to image the optical metrology target 104.

In some embodiments, an image of periodic features of an optical metrology target 104 is generated based on a single non-zero diffraction order from each illumination beam 108 in a pair of mutually-coherent illumination beams 108. Further, each pair of mutually-coherent illumination beams 108 may be azimuthally rotated relative to a direction of periodicity of features in the optical metrology target 104. In this way, the impact of zero-order side lobes (e.g., side lobes surrounding a peak of zero-order diffraction) may be mitigated, reduced, or eliminated through any combination of physical blocking of the zero-order side lobes in a collection pupil of the optical metrology sub-system 102 or algorithmic filtering of generated images (e.g., post-processing of the generated images).

The optical metrology system 100 may then generate optical metrology measurements for the sample 106 based on one or more of these images.

In some embodiments, the optical metrology system 100 includes a controller 114 communicatively coupled to the optical metrology sub-system 102, where the controller 114 includes one or more processors 116. For example, the one or more processors 116 may be configured to execute a set of program instructions maintained in a memory 118, or memory device.

The one or more processors 116 of a controller 114 may include any processing element known in the art. In this sense, the one or more processors 116 may include any microprocessor-type device configured to execute algorithms and/or instructions. Further, the memory 118 may include any storage medium known in the art suitable for storing program instructions executable by the associated one or more processors 116. For example, the memory 118 may include a non-transitory memory medium. As an additional example, the memory 118 may include, but is not limited to, a read-only memory, a random-access memory, a magnetic or optical memory device (e.g., disk), a magnetic tape, a solid-state drive and the like. It is further noted that the memory 118 may be housed in a common controller housing with the one or more processors 116.

The one or more processors 116 of the controller 114 may be configured to execute program instructions causing the one or more processors 116 to perform various process steps disclosed herein either directly or indirectly. For example, the program instructions may cause the one or more processors 116 to generate control signals for any additional components (e.g., the optical metrology sub-system 102, or any components therein) to perform various actions such as, but not limited to, generating images of an optical metrology target 104. As another example, the program instructions may cause the one or more processors 116 to generate one or more optical metrology measurements based on the acquired images.

Referring now to FIG. 1B, various aspects of the optical metrology sub-system 102 are described in greater detail, in accordance with one or more embodiments of the present disclosure. FIG. 1B illustrates a simplified schematic view of an optical metrology sub-system 102 suitable for illuminating an optical metrology target 104 with one or more pairs of mutually-coherent illumination beams 108 and imaging the optical metrology target 104 based on a single non-zero diffraction order from each illumination beam 108, in accordance with one or more embodiments of the present disclosure.

The optical metrology target 104 and/or the optical metrology sub-system 102 may be configured to according to a metrology recipe suitable for generating optical metrology measurements based on a desired technique. More generally, the optical metrology sub-system 102 may be configurable according to a variety of metrology recipes to perform optical metrology measurements using a variety of techniques and/or perform optical metrology measurements on a variety of different designs of an optical metrology target 104.

For example, a metrology recipe may include various aspects of an optical metrology target 104 or a design of an optical metrology target 104 including, but not limited to, a layout of target features on one or more sample layers, feature sizes, or feature pitches. As another example, a metrology recipe may include parameters of illumination beams 108 such as, but not limited to, an illumination wavelength, an illumination pupil distribution (e.g., a distribution of illumination angles and associated intensities of illumination at those angles), a polarization of incident illumination, a spatial distribution of illumination, or a sample height. By way of another example, a metrology recipe may include collection parameters such as, but not limited to, a collection pupil distribution (e.g., a desired distribution of angular light from the sample to be used for a measurement and associated filtered intensities at those angles), collection field stop settings to select portions of the sample of interest, polarization of collected light, or wavelength filters.

In some embodiments, the optical metrology sub-system 102 is configured (e.g., according to a metrology recipe) to image an optical metrology target 104 having periodic structures using a single non-zero diffraction order from each illumination beam 108 in a pair of mutually-coherent illumination beams 108. In this configuration, the optical metrology sub-system 102 may provide a dark-field image since zero-order diffraction of the illumination beams 108 does not contribute to image formation. Further, since each pair of illumination beams 108 is mutually coherent, the single diffraction lobe associated with each illumination beam 108 in the pair interfere to form a sinusoidal interference pattern in the image (e.g., a pattern of sinusoidal interference fringes). In particular, the periodicity of sinusoidal interference does not correspond to a periodicity of features on the overlay target, but rather will be dependent on multiple factors including, but not limited to, a pitch of grating structures in the optical metrology target 104 (e.g., first-layer gratings 304 and/or second-layer gratings 306), wavelength of the illumination beams 108, polar incidence angle of the illumination beams 108, and the azimuthal incidence angle (e.g., a difference between the azimuth incidence angle of the illumination beams 108 relative to a characterized direction of periodicity).

As a result, the various grating structures in the optical metrology target 104 may be imaged with high contrast as pure sinusoids such that optical metrology measurements may be generated based on comparisons of relative phases of the neighboring cell images in accordance with a metrology recipe.

In some embodiments, the optical metrology sub-system 102 includes at least one illumination source 120 configured to generate the one or more pairs of mutually-coherent illumination beams 108. For example, the illumination beams 108 in a pair may have sufficient temporal and/or spatial coherence such that diffraction orders from different illumination beams 108 in the pair they may interfere at the detector 132 to form a high-contrast sinusoidal image of periodic features on the optical metrology target 104.

Each illumination beam 108 may include one or more selected wavelengths of light including, but not limited to, ultraviolet (UV) radiation, visible radiation, or infrared (IR) radiation.

The illumination source 120 may include any type of illumination source suitable for providing at least one pair of mutually-coherent illumination beams 108. In some embodiments, the illumination source 120 includes at least one laser source. For example, the illumination source 120 may include, but is not limited to, one or more narrowband laser sources, a broadband laser source, a supercontinuum laser source, a white light laser source, or the like. In this regard, the illumination source 120 may provide an illumination beam 108 having high coherence (e.g., high temporal coherence and/or spatial coherence).

In some embodiments, the optical metrology sub-system 102 includes illumination optics to direct the various illumination beams 108 to an optical metrology target 104 on the sample 106 through one or more illumination channels 122 (e.g., illumination channel 122a and illumination channel 122b in FIG. 1B). Further, the sample 106 may be disposed on a sample stage (not shown) suitable for securing the sample 106 and further configured to position the optical metrology target 104 with respect to the illumination beams 108.

It is noted that FIG. 1B illustrates the illumination of an optical metrology target 104 with a single pair of mutually-coherent illumination beams 108. In some embodiments, the optical metrology sub-system 102 illuminates an optical metrology target 104 with two pairs of mutually-coherent illumination beams 108. In this configuration, the optical metrology sub-system 102 may include an additional pair of illumination channels providing illumination beams 108 with different opposing azimuth incidence angles.

Each of the illumination channels 122 may include one or more optical components suitable for modifying and/or conditioning an illumination beam 108 as well as directing the illumination beam 108 to the optical metrology target 104. For example, each of the illumination channels 122 may include, but is not required to include, one or more illumination lenses 124 (e.g., to control a spot size of the illumination beam 108 on the optical metrology target 104, to relay pupil and/or field planes, or the like), one or more polarizers to adjust the polarization of the illumination beam 108 in the channel, one or more filters, one or more beam splitters, one or more diffusers, one or more homogenizers, one or more apodizers, one or more beam shapers, or one or more mirrors (e.g., static mirrors, translatable mirrors, scanning mirrors, or the like).

In some embodiments, the optical metrology sub-system 102 includes imaging optics within a collection pathway 126 for the collection of light from the sample light 112. In some embodiments, the collection pathway 126 includes an objective lens 110 to collect diffracted or scattered light from the optical metrology target 104. For example, the objective lens 110 may collect one or more diffracted orders of radiation from the optical metrology target 104 in response to the illumination beams 108.

The collection pathway 126 may further include multiple optical elements to direct and/or modify illumination collected by the objective lens 110 including, but not limited to one or more lenses 128, one or more filters, one or more polarizers, one or more beam blocks, or one or more beamsplitters. Such elements may be located in any suitable location in the collection pathway 126 including, but not limited to, a collection pupil 130.

In some embodiments, the collection pathway 126 includes a detector 132 configured to generate an image (e.g., a dark-field image) of the optical metrology target 104. For example, a detector 132 may receive an image of the sample 106 provided by elements in the collection pathway 126 (e.g., the objective lens 110, the one or more lenses 128, or the like).

For example, FIG. 1B illustrates generating a dark-field image of an optical metrology target 104 with a single non-zero diffraction order (e.g., light associated with a single first diffraction order) from each illumination beam 108 of a pair of mutually-coherent illumination beams 108. In particular, FIG. 1B illustrates the collection of a first non-zero diffraction order 134a associated with a first illumination beam 108a and the collection of a second non-zero diffraction order 134b associated with a second illumination beam 108b, where illumination beams 108a,b are mutually coherent.

It is contemplated herein that optical metrology based on dark-field imaging using mutually-coherent pairs of illumination beams 108 as disclosed herein may provide multiple advantages relative to existing image-based optical metrology techniques based on spatially-incoherent illumination including, but not limited to, support of fine grating pitches, high image contrast, high image brightness, matched brightness between cells of an optical metrology target, insensitivity to monochromatic aberrations (e.g., defocus, or the like), minimal encroachment of cell edges, and/or minimal stray light.

For example, image contrast of periodic features is high (maximized in some cases) when generating an image by interfering wavefronts from only two non-zero diffracted orders with equal amplitudes. As another example, image brightness is high (maximized in some cases) based on the use of spatially coherent laser illumination, which avoids light loss related to removing coherence for incoherent imaging with high-brightness laser sources. As another example in the case of an r-AIM optical metrology target 104, image brightness is matched between target cells since only grating pitches differ between cells. As another example, optical metrology measurements are insensitive to monochromatic aberrations and defocus due to the sampling of only two points in a pupil by the collected diffraction orders and further due to the sampling of the same points by cells from different layers. As another example, the use of oblique illumination (and OTL (outside-the-lens) illumination in some cases) mitigates cell edge ringing in generated images. As another example, the use of OTL configurations in particular may further limit light loss of the mutually-coherent illumination beams 108 since they do not propagate through the objective lens. Such configurations also limit a number of ghost reflections or scattering sites since relatively fewer optical surfaces are used as well as mitigate back-scattered illumination onto an imaging detector.

It is contemplated herein that the illumination channels 122 and the collection pathway 126 of the optical metrology sub-system 102 may be oriented in a wide range of configurations suitable for generating a dark-field image of the optical metrology target 104. For example, FIG. 1B illustrates an OTL configuration in which the various illumination beams 108 are directed to the optical metrology target 104 outside of a NA of the objective lens 110. In some embodiments, the optical metrology sub-system 102 directs the illumination beams 108 to the optical metrology target 104 within the NA of the objective lens 110 in a TTL (through-the-lens) configuration. For example, the optical metrology sub-system 102 may include one or more components common to the collection pathway 126 and the illumination channels 122 to simultaneously provide the illumination beams 108 to the objective lens 110 for illumination of the optical metrology target 104 and direct a single non-zero diffraction order to the detector 132 to contribute to an image of the optical metrology target 104. As a non-limiting illustration, the optical metrology sub-system 102 may include an annular mirror located at or near a pupil plane common to both the collection pathway 126 (e.g., conjugate to the collection pupil 130) and the illumination channels 122 (e.g., conjugate to an illumination pupil (not explicitly shown)). Such an annular mirror may direct the various illumination beams 108 to the objective lens 110. Such an annular mirror may further block zero-order diffraction of the illumination beams 108 while passing non-zero diffraction orders through a central opening to provide dark-field imaging with high contrast as described herein.

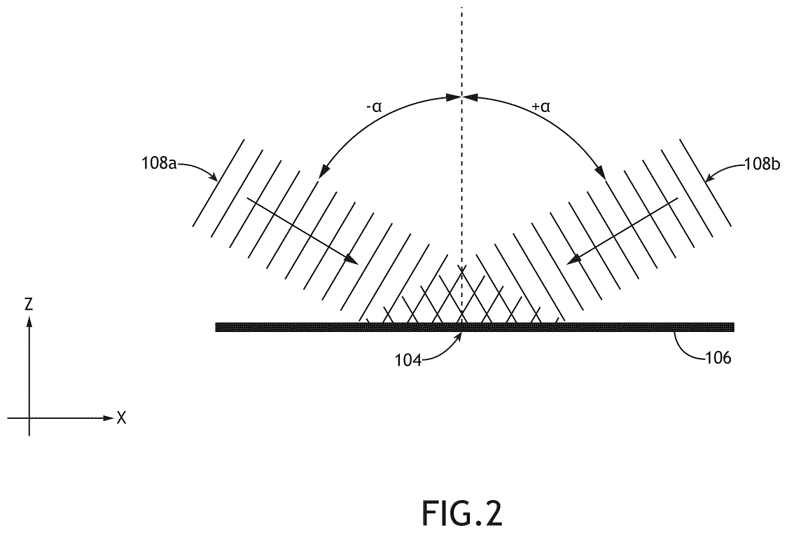

Referring now to FIGS. 2-6, optical metrology with pairs of mutually-coherent illumination beams 108 is described, in accordance with one or more embodiments of the present disclosure.

FIG. 2 illustrates a conceptual diagram of illuminating an optical metrology target 104 with a pair of mutually-coherent illumination beams 108, in accordance with one or more embodiments of the present disclosure. FIG. 2 depicts two illumination beams 108a,b as a pair of mutually-coherent illumination beams 108, where each illumination beam 108 is depicted as providing a planar wavefront. In some embodiments, the optical metrology sub-system 102 directs a pair of mutually-coherent illumination beams 108 at symmetric incidence angles. For example, the illumination beams 108a,b have symmetric polar incidence angles (±α) and symmetric (e.g., opposing) azimuth incidence angles. In FIG. 2, this is illustrated by the two illumination beams 108a,b propagating in opposite azimuth directions in a plane of the figure.

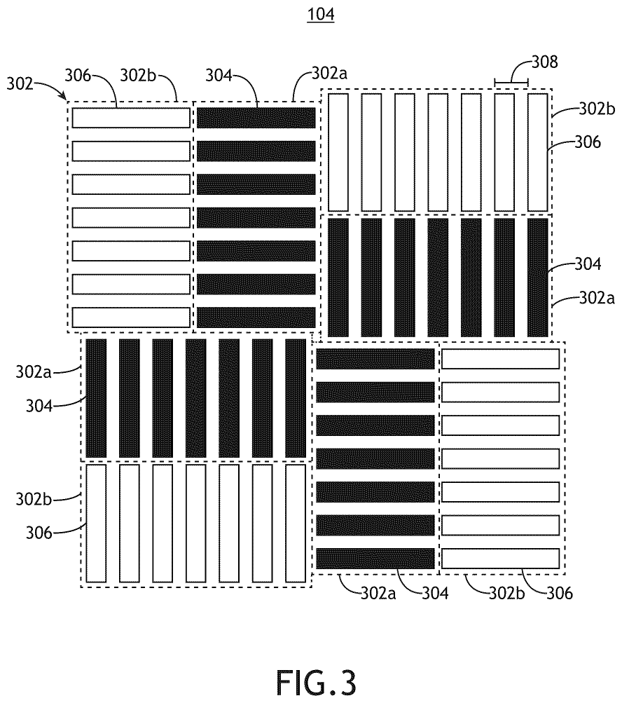

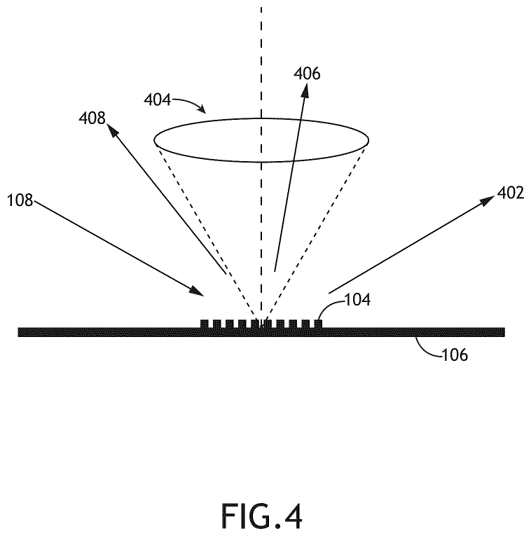

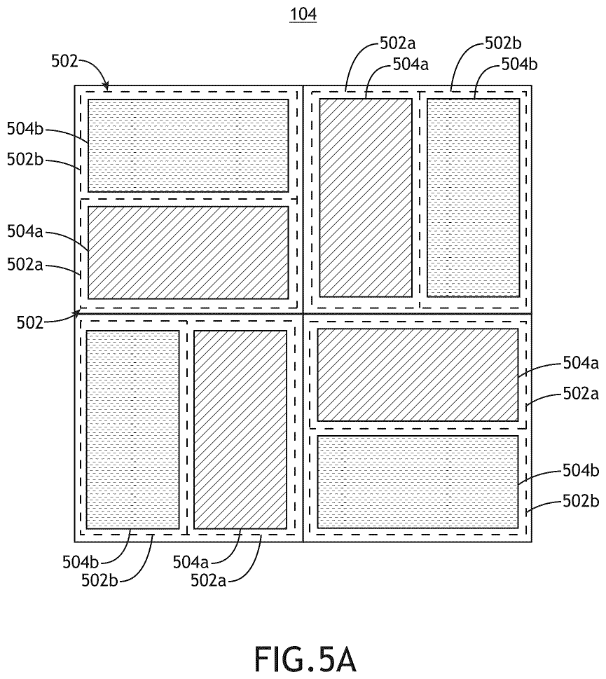

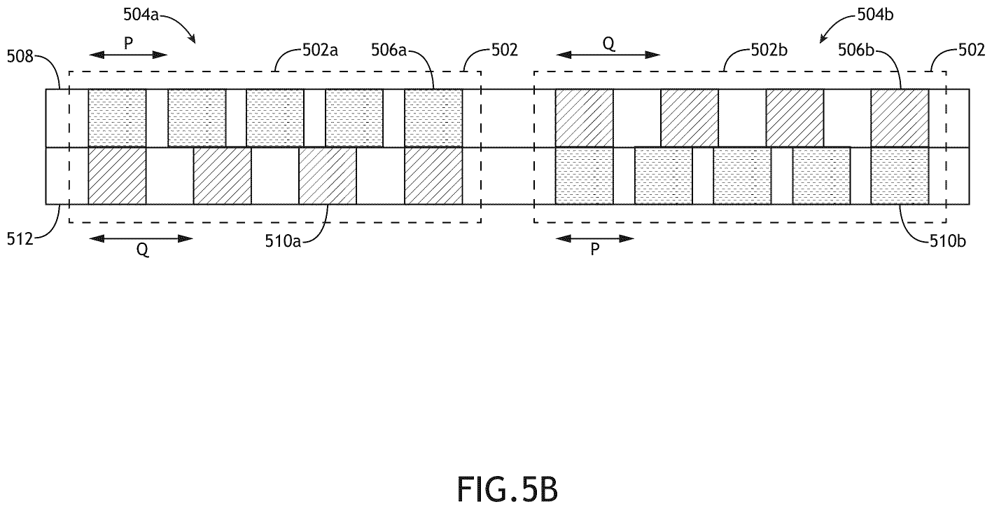

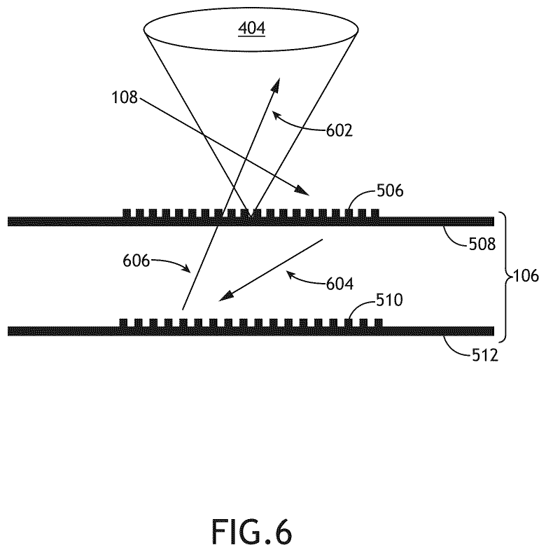

FIGS. 3-6 depict imaging with a single non-zero diffraction order from each of the illumination beams 108 for various non-limiting designs of an optical metrology target 104. In particular, FIGS. 3-4 depict AIM targets and FIGS. 5A-6 depict r-AIM targets.

FIG. 3 illustrates a top view of an AIM optical metrology target 104, in accordance with one or more embodiments of the present disclosure. In one embodiment, the optical metrology target 104 includes various cells 302, each including a single grating located on a single layer of the sample 106. For example, the optical metrology target 104 may include one or more cells 302a with first-layer gratings 304 on a first layer of the sample 106 and one or more cells 302b second-layer gratings 306 on a second layer of the sample 106. Further, each of the first-layer gratings 304 and the second-layer gratings 306 are formed from features having a common pitch 308. In this regard, diffraction orders from the first-layer gratings 304 and the second-layer gratings 306 may be collocated in the collection pupil 130. Such an optical metrology target 104 may be suitable for, but not limited to, overlay measurements based on a relative shift between the first-layer gratings and the second-layer gratings.

FIG. 4 illustrates a conceptual schematic illustrating the collection of a single non-zero diffraction order from an AIM optical metrology target 104, in accordance with one or more embodiments of the present disclosure. FIG. 4 depicts an illumination beam 108 directed to an optical metrology target 104 using an OTL configuration such as that depicted in FIG. 1B. In this configuration, a zero-order diffraction pole 402 (e.g., specular reflection) from the sample 106 naturally lies outside a collection NA 404 (e.g., a NA of the objective lens 110). FIG. 4 further depicts a first-order diffraction pole 406 within the collection NA 404, while a second-order diffraction pole 408 lies outside the collection NA 404 and thus does not contribute to image formation.

It is noted that FIG. 4 depicts illumination and collection based on only one illumination beam 108 of a pair of mutually-coherent illumination beams 108 for clarity. It is to be understood illumination with the other illumination beam 108 in the pair of mutually-coherent illumination beams 108 produces a similar result based on the illumination symmetry.

It is to be understood that although FIG. 4 depicts an OTL configuration, a similar result may be achieved with a TTL configuration when the zero-order diffraction pole 402 (e.g., specular reflection and zero-order diffraction) is blocked in the collection pathway 126 (e.g., by an element in the collection pupil 130). Further, a metrology recipe may be configured to provide a combination of grating pitch 308 and wavelength of the illumination beams 108 that satisfies the requirement of collecting only a single non-zero diffraction order (e.g., the first-order diffraction pole 406) for each illumination beam 108 using an AIM optical metrology target 104.

FIGS. 5A and 5B illustrate an r-AIM optical metrology target 104, in accordance with one or more embodiments of the present disclosure. FIG. 5A illustrates a top view of an r-AIM optical metrology target 104, in accordance with one or more embodiments of the present disclosure. FIG. 5B illustrates a side view of two adjacent cells 502 (e.g., cell 502a and cell 502b) including Moiré structures (e.g., Moiré structure 504a and Moiré structure 504b) that may form a quadrant of an r-AIM optical metrology target 104 as depicted in FIG. 5A, in accordance with one or more embodiments of the present disclosure.

A Moiré structure 504a,b may include two gratings in overlapping regions of the sample 106, where the two gratings have different pitches. In some embodiments, a r-AIM optical metrology target 104 includes adjacent Moiré structures 504 having opposite pitches in the corresponding layers. In this way, a measurement error on the sample 106 may cause Moiré diffraction orders associated with a Moiré pitch to move in opposite directions for the two adjacent Moiré structures 504.

For example, FIG. 5B illustrates a first Moiré structure 504a having an upper grating 506a with a first pitch (P) on a first layer 508 of the sample 106 and a lower grating 510a with a second pitch (Q) on a second layer 512 of the sample 106. FIG. 5B also illustrates a second Moiré structure 504b having an upper grating 506b with the second pitch (Q) on the first layer 508 of the sample 106 and a lower grating 510b with the first pitch (P) on the second layer 512 of the sample 106.

FIG. 6 illustrates a conceptual schematic illustrating the collection of a single non-zero diffraction order from an r-AIM optical metrology target 104, in accordance with one or more embodiments of the present disclosure. FIG. 6 depicts an illumination beam 108 directed to an optical metrology target 104 using an OTL configuration such as that depicted in FIG. 1B. As with FIG. 4, a zero-order diffraction pole (not shown in FIG. 6 for clarity) lies outside the collection NA 404 (e.g., a NA of the objective lens 110).

FIG. 6 further depicts a Moiré diffraction pole 602 (e.g., from a Moiré diffraction order) associated with first-order diffraction from both gratings entering the collection NA 404. For example, the Moiré diffraction pole 602 is formed from a first-order diffraction pole 604 from the upper grating 506 that serves as the basis of a first-order diffraction pole 606 from the lower grating 510.

It is noted that FIG. 6 depicts illumination and collection based on only one illumination beam 108 of a pair of mutually-coherent illumination beams 108 for clarity. It is to be understood illumination with the other illumination beam 108 in the pair of mutually-coherent illumination beams 108 produces a similar result based on the illumination symmetry.

It is to be understood that although FIG. 6 depicts an OTL configuration, a similar result may be achieved with a TTL configuration when zero-order diffraction poles are blocked in the collection pathway 126 (e.g., by an element in the collection pupil 130). In some embodiments, a metrology recipe provides the conditions under which all light diffracted from one of the gratings of a Moiré structure 504 fall outside the collection NA 404 and only one Moiré diffraction order associated with diffraction of light by each of the gratings of the Moiré structure 504 falls within the collection NA 404.

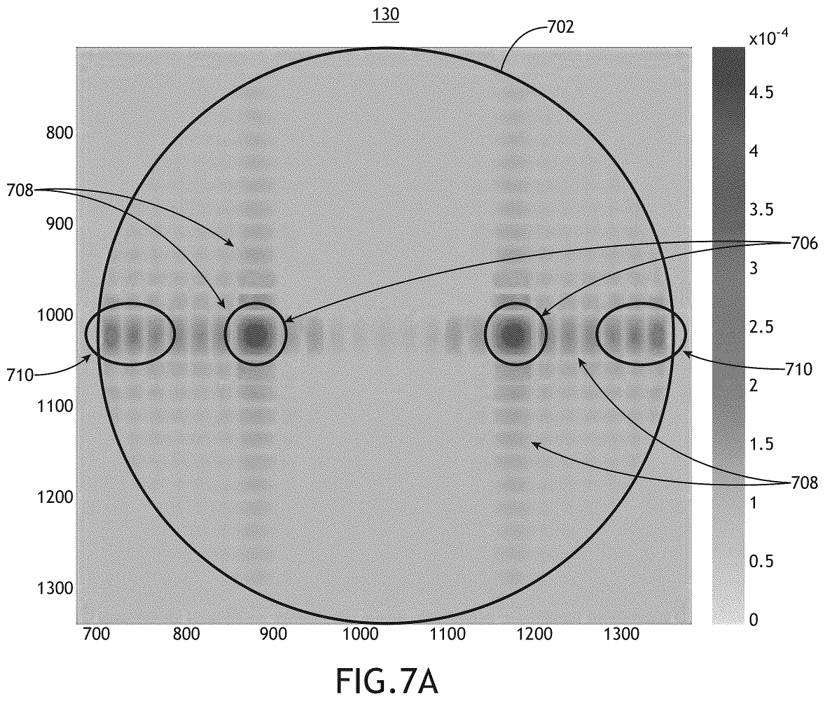

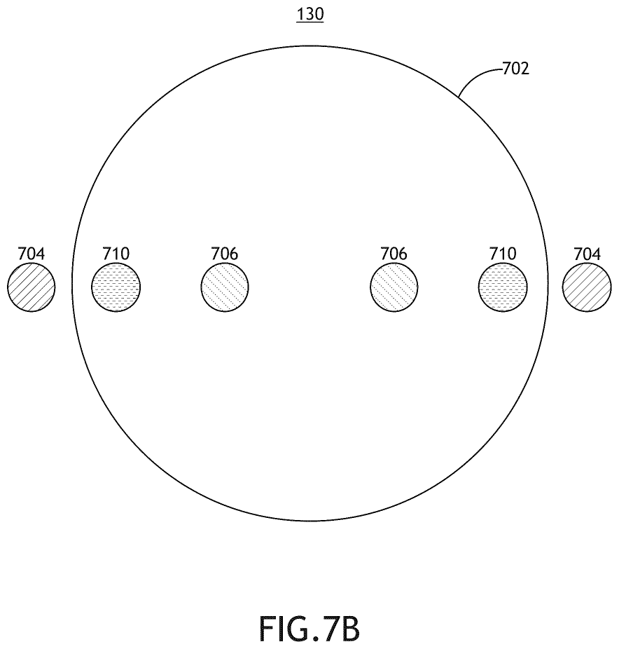

Referring now to FIGS. 7A-10, control over zero-order side lobes in optical metrology is described in greater detail, in accordance with one or more embodiments of the present disclosure.

FIG. 7A illustrates an image of a collection pupil 130 (e.g., a pupil image) of an optical metrology sub-system 102 associated with imaging an optical metrology target 104 using a mutually-coherent pair of illumination beams 108 with azimuth angles aligned with a direction of periodicity of features on the optical metrology target 104, in accordance with one or more embodiments of the present disclosure. FIG. 7B illustrates a simplified schematic of the collection pupil 130 associated with FIG. 7A, in accordance with one or more embodiments of the present disclosure.

In particular, FIGS. 7A-7B depict an OTL configuration with an optical metrology target 104 having outer dimensions of 8 μm based on illumination beams 108 having an NA of 0.93 and a collection NA of 0.8. The collection NA is shown as a circular collection pupil boundary 702 in FIGS. 7A-7B. In this OTL configuration, two zero-order diffraction poles 704 (e.g., poles associated with specular reflection of the illumination beams 108) are depicted outside the collection pupil boundary 702 in FIG. 7B and not shown in FIG. 7A since they are not collected by the objective lens 110.

FIGS. 7A-7B further depict two non-zero-order diffraction poles 706 inside the collection pupil boundary 702. For example, one non-zero-order diffraction pole 706 may be collected for each illumination beam 108 in a pair. As an illustration, the non-zero-order diffraction poles 706 may correspond to first-order diffraction poles from, Moiré diffraction poles, or poles associated with non-zero diffraction from any type of optical metrology target 104.

FIGS. 7A-7B further depict various side lobes surrounding the diffraction poles. As described previously herein, side lobes may be associated with any phenomenon such as, but not limited to, diffraction from edges of the optical metrology target 104 or cells therein.

For example, FIG. 7A depicts non-zero-order side lobes 708 extending along both X and Y directions from the non-zero-order diffraction poles 706. FIG. 7A further depicts zero-order side lobes 710 extending inward from the collection pupil boundary 702 that are associated with the uncollected zero-order diffraction poles 704. In FIG. 7A, the non-zero-order side lobes 708 and the zero-order side lobes 710 are depicted a series of peaks with decreasing intensity surrounding the central pole. In FIG. 7B, the locations of zero-order side lobes 710 are simply depicted as circles.

It is contemplated herein that in the configuration depicted in FIGS. 7A-7B, there may be uncontrolled phase differences between plane waves associated with the first-order light that may arise from various conditions such as, but not limited to, mechanical vibrations). When no zero-order side lobes 710 are collected, such phase differences may be the same for different layers of the sample 106 and should thus not impact an optical metrology measurement.

However, when zero-order side lobes 710 overlap with first-order light (e.g., non-zero-order side lobes 708 and/or non-zero-order diffraction poles 706 as depicted in FIG. 7A), the associated interference may produce a signal modulation that depends on the phase between the associated plane waves, which may impact the accuracy of an optical metrology measurement. Further, a strength of the various side lobes (e.g., the non-zero-order side lobes 708 and the zero-order side lobes 710) may increase as the size of the optical metrology target 104 decreases. Put another way, edge diffraction effects associated with the generation of side lobes increase with smaller target sizes. As a result, the presence of side lobes may pose a practical constraint when reducing target size when using typical techniques.

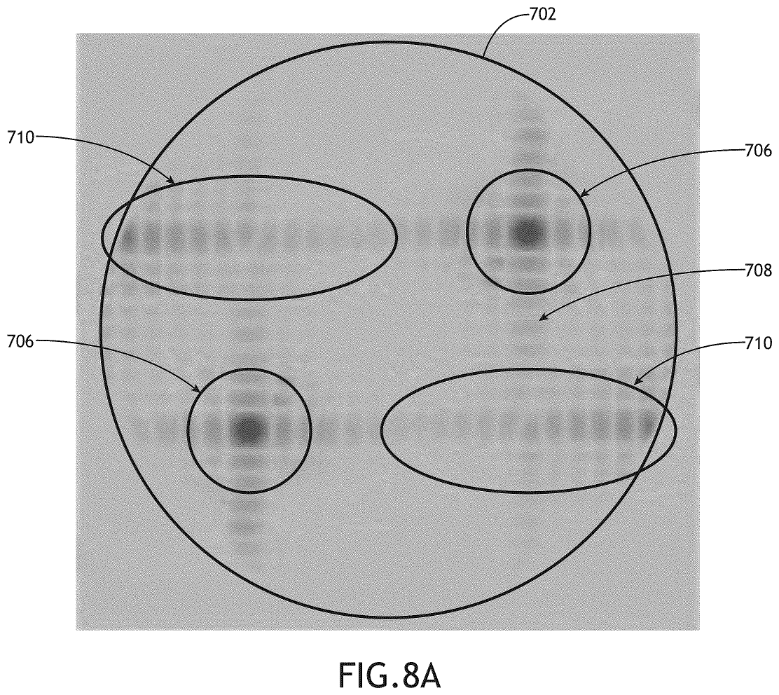

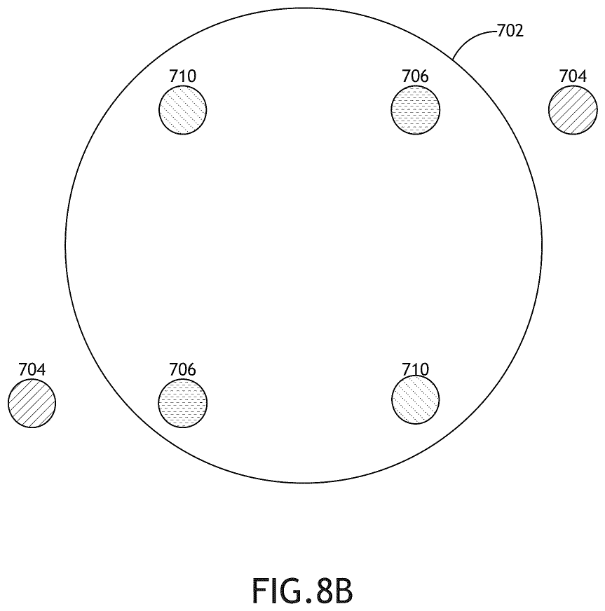

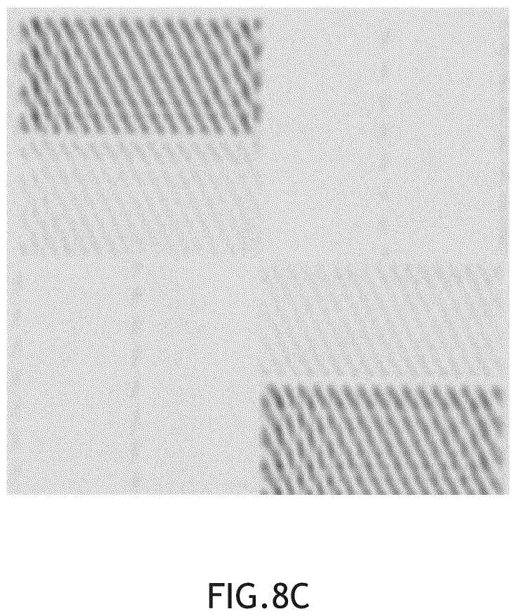

Referring now to FIGS. 8A-10, the mitigation of the impact of zero-order side lobes 710 by azimuthally rotating mutually-coherent pairs of illumination beams 108 relative to directions of periodicity of features on the optical metrology target 104 is described in greater detail, in accordance with one or more embodiments of the present disclosure.

FIG. 8A illustrates an image of a collection pupil 130 of an optical metrology sub-system 102 associated with imaging an optical metrology target 104 using a mutually-coherent pair of illumination beams 108 with azimuth angles rotated with respect to a direction of periodicity of features on the optical metrology target 104, in accordance with one or more embodiments of the present disclosure. FIG. 8B illustrates a simplified schematic of the collection pupil 130 associated with FIG. 8A, in accordance with one or more embodiments of the present disclosure. FIGS. 8A-8B depict the same configuration of the optical metrology target 104 and the optical metrology sub-system 102 as in FIGS. 7A-7B, except that the illumination beams 108 are rotated.

It is contemplated herein that rotating a pair of mutually-coherent illumination beams 108 relative to a direction of periodicity of features on an optical metrology target 104 may provide numerous benefits that enable accurate measurements on small optical metrology targets 104.

For example, as shown in FIGS. 8A-8B, rotating a pair of mutually-coherent illumination beams 108 relative to a direction of periodicity of features on an optical metrology target 104 may spatially separate zero-order side lobes 710 from non-zero-order diffraction (e.g., non-zero-order side lobes 708 and/or non-zero-order diffraction poles 706) in the collection pupil plane, which substantially reduces the interference of such light and any associated impact on an optical metrology measurement. For example, FIG. 8A depicts clear separation between zero-order side lobes 710 and non-zero-order diffraction poles 706, as well as reduced overlap of zero-order side lobes 710 with non-zero-order side lobes 708 (e.g., overlap in regions of relatively low intensity).

Rotating a pair of mutually-coherent illumination beams 108 relative to a direction of periodicity of features on an optical metrology target 104 may further enable the use of a higher collection NA than typical techniques while maintaining desired image properties (e.g., image contrast, image brightness, or the like). In particular, the NA of the objective lens 110 may be increased such that the collection pupil boundary 702 is closer to the zero-order diffraction poles 704 without meaningfully degrading the image of the optical metrology target 104. Even though increasing the NA of the objective lens 110 increases the signal strength of collected zero-order side lobes 710, this additional portion of the zero-order side lobes 710 does not overlap with non-zero diffraction (or the non-zero diffraction has negligible intensity in these regions).

Additionally, this rotated illumination configuration enables various techniques for further mitigating any residual impact of the zero-order side lobes 710.

In some embodiments, remaining interference between zero-order side lobes 710 and non-zero-order light (e.g., the low-intensity non-zero-order side lobes 708) is at least partially filtered from an image of the optical metrology target 104 based on fringe orientation. For example, fringes in an image of the optical metrology target 104 associated with interference between zero-order side lobes 710 and non-zero-order light (e.g., the low-intensity non-zero-order side lobes 708) may be oriented at a different angle than fringes associated with interference between non-zero-order diffraction from a pair of mutually-coherent illumination beams 108. Accordingly, one or more image processing techniques (e.g., algorithmic techniques) such as, but not limited to, spatial Fourier Transform filtering techniques, may be utilized to filter out signals associated with the zero-order side lobes 710 from an image of the optical metrology target 104.

As an illustration, FIG. 8C illustrates an image of an optical metrology target 104 generated with a rotated pair of illumination beams 108 as shown in FIGS. 8A-8B, in accordance with one or more embodiments of the present disclosure. In FIG. 8C, the image includes relatively strong diagonal fringes associated with the mutually-coherent pair of illumination beams 108 and relatively weak vertical fringes associated with interference between zero-order side lobes 710 and non-zero-order side lobes 708 as shown in FIG. 8A. Such vertical fringes may be removed to further mitigate the impact of the zero-order side lobes 710 on an optical metrology measurement.

In some embodiments, at least a portion of the zero-order side lobes 710 is blocked from reaching a detector 132 and thus blocked from contributing to forming an image of the optical metrology target 104. For example, the optical metrology sub-system 102 may include one or more components in the collection pathway 126 (e.g., in the collection pupil 130) to selectively block at least a portion of the zero-order diffraction poles 704.

As an illustration, the optical metrology sub-system 102 may include one or more blockers (e.g., beam blocks) in upper-left and lower-right portions of the collection pupil 130 to block the zero-order side lobes 710 shown in FIGS. 8A-8B.

It is noted that although FIGS. 7A-8C depict conditions for imaging with a single pair of mutually-coherent illumination beams 108, this is merely an illustration. In a general sense, an optical metrology system 100 may image an optical metrology target 104 with multiple pairs of mutually-coherent illumination beams 108.

For example, an optical metrology sub-system 102 may include a first pair of mutually-coherent illumination beams 108 to image features of an optical metrology target 104 with periodicity along a first direction (e.g., an X direction) and may further include a second pair of mutually-coherent illumination beams 108 to image features of an optical metrology target 104 with periodicity along a second direction (e.g., a Y direction). In these configurations, the different pairs of mutually-coherent illumination beams 108 may be directed to the optical metrology target 104 either sequentially or simultaneously. For instance, the azimuth incidence angles of the first pair of mutually-coherent illumination beams 108 may be selected (e.g., in accordance with a metrology recipe) such that only a single non-zero diffraction order along the X direction is collected (or passed to the detector 132). Similarly, the azimuth incidence angles of the second pair of mutually-coherent illumination beams 108 may be selected (e.g., in accordance with a metrology recipe) such that only a single non-zero diffraction order along the Y direction is collected (or passed to the detector 132).

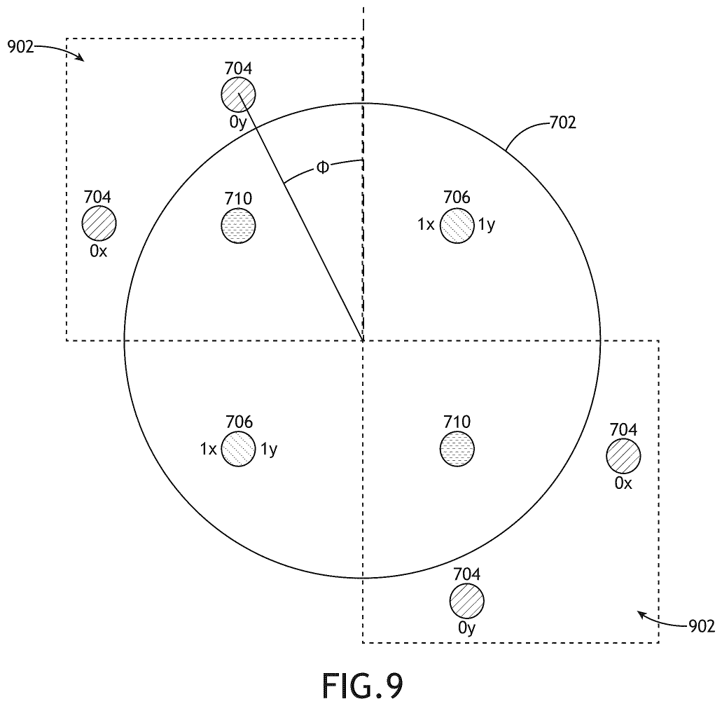

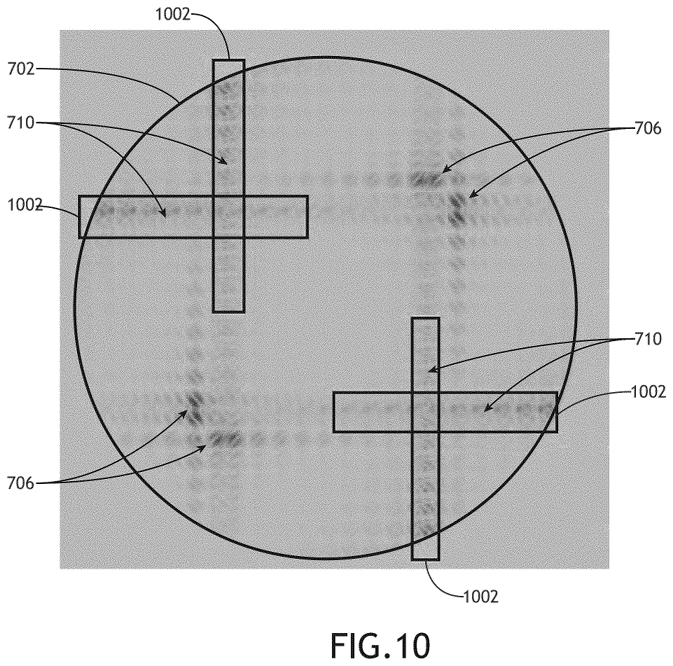

FIGS. 9-10 depict non-limiting configurations for blocking zero-order side lobes 710 in configurations with two pairs of mutually-coherent illumination beams 108, in accordance with one or more embodiments of the present disclosure.

FIG. 9 illustrates a simplified schematic of a collection pupil 130 of an optical metrology sub-system 102 having features with periodicity along both the X and Y directions imaged with two pairs of mutually-coherent illumination beams 108, in accordance with one or more embodiments of the present disclosure. For example, one pair of mutually-coherent illumination beams 108 may provide imaging of features with periodicity along the X direction and another pair of mutually-coherent illumination beams 108 may provide imaging of features with periodicity along the Y direction.

FIG. 9 depicts a first pair of zero-order diffraction poles 704 (0x) associated with a first pair of mutually-coherent illumination beams 108 (not shown) that have azimuth angles rotated to provide imaging of features with periodicity along the X direction based on non-zero-order diffraction poles 706 (1x) associated with diffraction of the first pair of mutually-coherent illumination beams 108 (not shown) along the X direction.

FIG. 9 further depicts a second pair of zero-order diffraction poles 704 (0y) associated with a second pair of mutually-coherent illumination beams 108 (not shown) that have azimuth angles rotated to provide imaging of features with periodicity along the Y direction based on non-zero-order diffraction poles 706 (1y) associated with diffraction of the second pair of mutually-coherent illumination beams 108 (not shown) along the Y direction.

FIG. 9 also depicts zero-order side lobes 710 associated with the various zero-order diffraction poles 704.

It is to be understood that the arrangement of various diffraction lobes in FIG. 9 is merely illustrative and should not be interpreted as limiting the scope of the present disclosure. For example, FIG. 9 depicts the zero-order side lobes 710 associated with the various zero-order diffraction poles 704 along X and Y directions as overlapping (or close together in the collection pupil 130. However, this is merely illustrative and the positions of the zero-order side lobes 710 are generally determined by the azimuth angles of the associated illumination beams 108. As another example, FIG. 9 depicts the non-zero-order diffraction poles 706 associated with X and Y diffraction as overlapping (or are close together) in the collection pupil 130. This is also merely illustrative and the positions of the non-zero-order diffraction poles 706 may generally depend on the specific azimuth angles of a corresponding pair of mutually-coherent illumination beams 108 as well as the pitch of the corresponding features on an optical metrology target 104 and may generally be located anywhere in the collection pupil 130.

In some embodiments, an optical metrology sub-system 102 includes one or more blockers 902 (e.g., at a collection pupil 130) oriented to selectively block at least a portion of zero-order side lobes 710. As described previously herein, the impact of zero-order side lobes 710 on an optical metrology measurement may be mitigated through any combination of physical blocking of at least portions of the zero-order side lobes 710 or image processing techniques.

As shown in FIG. 9, zero-order side lobes 710 may be grouped together through appropriate selection of the azimuth angles of the pairs of mutually-coherent illumination beams 108. For example, FIG. 9 illustrates a configuration in which the non-zero-order diffraction poles 706 are arranged within a first set of diagonal quadrants of the collection pupil boundary 702 and in which the zero-order side lobes 710 may be arranged within a second set of diagonal quadrants. As a result, blockers 902 in this second set of diagonal quadrants may effectively block the zero-order side lobes 710 and pass the desired non-zero-order diffraction poles 706 (and associated non-zero-order side lobes 708). This configuration is achieved by rotating the two pairs of mutually-coherent illumination beams 108 to be within diagonal quadrants of an illumination pupil plane.

However, there are some limitations of this configuration that provide sufficient separation between the zero-order side lobes 710 and the non-zero-order diffraction poles 706 (and associated non-zero-order side lobes 708). For example, only a certain range of rotation angles ϕ may result in the collection of a single non-zero-order diffraction pole 706 per illumination beam 108 as depicted in FIG. 9. In some embodiments, the maximum rotation angle ϕ may be governed by the expression:

$$cos ϕ < \frac{N {A}_{c o l l}}{N {A}_{illum}} \qquad ( 1 )$$

where NA_{coil} is a collection NA (e.g., a NA of the objective lens 110) and NAᵢₗₗᵢᵤₘ is an illumination NA (e.g., associated with a size of an illumination beam 108 in an illumination pupil and thus a size of diffraction poles in the collection pupil 130). As an example in the case of an illumination NA of 0.93 and a collection NA of 0.8, the maximum rotation angle (ϕ) is approximately 25°.

Another consideration related to the selection of a rotation angle ϕ is the separation distance D between the zero-order side lobes 710 and the non-zero-order diffraction poles 706. In a general sense, it may be desirable to maximize this distance D in all directions to effectively isolate the zero-order side lobes 710 and provide sufficient physical space for the blockers 902. For example, it may be desirable to have the distance D (e.g., in units of NA) be greater than or equal to a threshold value such as, but not limited to, 0.3, 0.5, 0.6, or any suitable value. Equation (2) may be, but is not required to be, used to relate a rotation angle ϕ to a threshold value DTH:

$$sin ϕ > \frac{{D}_{T H}}{N {A}_{illum}} \qquad ( 2 )$$

As an example in the case of an illumination NA of 0.93 and a threshold value DTH of 0.3, the minimum desirable value of the rotation angle ϕ is approximately 20 degrees.

In some embodiments, an optical metrology sub-system 102 includes one or more blockers tailored to shape of expected zero-order side lobes 710 (e.g., in accordance with a metrology recipe), which may be referred to as localized blocking. In this configuration, the shape and/or location of a blocker (e.g., in a collection pupil 130) may be selected to block zero-order side lobes 710.

FIG. 10 illustrates a pupil image of an optical metrology sub-system 102 depicting localized blocking of zero-order side lobes 710 associated with the collection pupil 130 configuration of FIG. 9, in accordance with one or more embodiments of the present disclosure. For example, FIG. 10 depicts the non-zero-order diffraction poles 706 (1_{X}, 1_{Y}) along both the X and Y directions from the two pairs of mutually-coherent illumination beams 108 schematically depicted in FIG. 9. FIG. 10 further depicts zero-order side lobes 710 extending from the illumination beams 108 along both X and Y directions (e.g., associated with edge diffraction along Y and X directions, respectively) and may be at least partially blocked using blockers 1002. It is contemplated herein that the positions of the zero-order side lobes 710 and thus the positions of the blockers 1002 may be determined by the azimuth incidence angles and intensity of the various illumination beams 108, but may be independent of the wavelength of the illumination beams 108 as well as the pitch of the features on the optical metrology target 104.

Further, the blockers 1002 may be implemented in a variety of ways within the spirit and scope of the present disclosure. For example, the blockers 1002 may be implemented as an aperture with fixed opaque portions forming the blockers 1002. As another example, the blockers 1002 may be provided by a programmable pixelated device such as, but not limited to, a micro-electro-mechanical system (MEMS) mirror or a spatial light modulator (SLM).

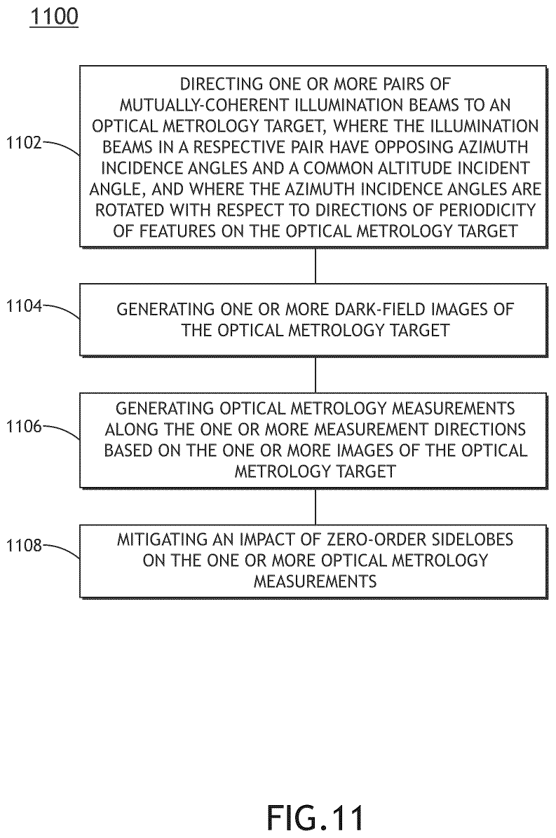

Referring now to FIG. 11, FIG. 11 illustrates a flow diagram illustrating steps performed in a method 1100 for optical metrology with mutually-coherent illumination beams 108, in accordance with one or more embodiments of the present disclosure. Applicant notes that the embodiments and enabling technologies described previously herein in the context of the optical metrology system 100 should be interpreted to extend to the method 1100. It is further noted, however, that the method 1100 is not limited to the architecture of the optical metrology system 100.

In some embodiments, the method 1100 includes a step 1102 of directing one or more pairs of mutually-coherent illumination beams 108 to an optical metrology target 104, where the illumination beams 108 in a respective pair have opposing azimuth incidence angles and a common altitude incidence angle (e.g., polar incidence angle), and where the azimuth incidence angles are rotated with respect to directions of periodicity of features on the optical metrology target 104 (e.g., corresponding to measurement directions). For example, the optical metrology target 104 may include one or more sets of periodic features associated with two or more different lithographic exposures, where the one or more sets of periodic features have periodicity along one or more measurement directions. Further, the illumination beams 108 in a respective pair of mutually-coherent illumination beams 108 may have opposing azimuth incidence angles and a common altitude incidence angle, where the azimuth incidence angles are rotated with respect to the one or more measurement directions.

In some embodiments, the method 1100 includes a step 1104 of generating one or more dark-field images of the optical metrology target 104. For example, an image of a particular one of the one or more sets of periodic structures may include a sinusoidal interference pattern generated by interference of a single non-zero diffraction order of light from each of the illumination beams 108 within a particular pair mutually-coherent illumination beams 108. For example, the single non-zero diffraction order may correspond to a first diffraction order (e.g., first-order diffraction), a Moiré diffraction order, or any other non-zero diffraction order.

In some embodiments, the method 1100 includes a step 1106 of generating optical metrology measurements along the one or more measurement directions based on the one or more images of the optical metrology target 104. Any suitable technique may be used to generate optical metrology measurements based on the images. For example, the optical metrology measurements may be generated based on differences of centers of symmetry of sets of periodic features from different lithographic exposures.

In some embodiments, the method 1100 includes a step 1108 of mitigating an impact of zero-order side lobes on the one or more optical metrology measurements. As described throughout the present disclosure, interference between zero-order side lobes and non-zero-order light may negatively impact an accuracy, sensitivity, and/or precision of optical metrology measurements. Further, an intensity of zero-order side lobes may increase as a size of the optical metrology target 104 decreases such that zero-order side lobes may present a constraint on target size reduction.

Zero-order side lobes may be mitigated in step 1108 through any combination of physical blocking or image processing techniques.

For example, step 1108 may include blocking at least a portion of zero-order side lobes from reaching a detector generating the one or more images. In this way, interference between zero-order side lobes and non-zero-order light may be prevented.

As another example, step 1108 may include filtering one or more signals associated with interference between the zero-order side lobes and any of the first-order diffraction lobes from the one or more images to generate one or more filtered images. For example, undesirable interference between the zero-order side lobes and any of the first-order diffraction lobes may have a fringe direction and/or spatial frequency compared to desirable interference between non-zero diffraction from a pair of mutually-coherent illumination beams 108. In this configuration, any type of filtering technique may be used such as, but not limited to, spatial Fourier Transform filtering.

The herein described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An optical metrology system, comprising:
one or more illumination optics configured to direct one or more pairs of mutually-coherent illumination beams to an optical metrology target on a sample in accordance with a metrology recipe, wherein the optical metrology target in accordance with the metrology recipe includes one or more sets of periodic features associated with two or more different lithographic exposures, wherein the one or more sets of periodic features have periodicity along one or more measurement directions, wherein the illumination beams in a respective pair of the mutually-coherent illumination beams are directed to the sample with opposing azimuth incidence angles and a common altitude incidence angle, wherein the opposing azimuth incidence angles of the one or more pairs of the mutually-coherent illumination beams are azimuthally rotated with respect to the one or more measurement directions;
an imaging sub-system including an objective lens configured to provide dark-field imaging of the optical metrology target on a detector located at a field plane conjugate to the optical metrology target in accordance with the metrology recipe, wherein an image of a particular one of the one or more sets of periodic features includes a sinusoidal interference pattern generated by interference of a single non-zero diffraction order of light from each of the illumination beams within a particular pair of the one or more pairs of the mutually-coherent illumination beams; and
a controller including one or more processors configured to execute program instructions causing the one or more processors to generate one or more optical metrology measurements along the one or more measurement directions based on one or more images of the optical metrology target received from the detector.

2. The optical metrology system of claim 1, wherein the objective lens collects at least some zero-order side lobes from the one or more pairs of the mutually-coherent illumination beams, wherein the imaging sub-system further includes one or more blockers to prevent at least some of the zero-order side lobes collected by the objective lens from reaching the detector.

3. The optical metrology system of claim 2, wherein the one or more blockers are located in opposing quadrants of a pupil plane of the imaging sub-system.

4. The optical metrology system of claim 1, wherein the objective lens collects at least some zero-order side lobes from the one or more pairs of the mutually-coherent illumination beams, wherein the program instructions are further configured to cause the one or more processors to generate the one or more optical metrology measurements by:
filtering one or more signals associated with interference between the zero-order side lobes collected by the objective lens and any of the non-zero diffraction orders from the one or more images to generate one or more filtered images; and
generating the one or more optical metrology measurements based on the one or more filtered images.

5. The optical metrology system of claim 4, wherein the one or more signals in the one or more images associated with interference between the zero-order side lobes collected by the objective lens and any of the non-zero diffraction orders include interference fringes along a different direction than interference between the non-zero diffraction orders, wherein filtering the one or more signals comprises filtering the one or more signals based on fringe direction.

6. The optical metrology system of claim 1, wherein the one or more sets of periodic features on the optical metrology target comprise:
a first-layer grating on a first layer of the sample; and
a second-layer grating on a second layer of the sample, wherein the first and second-layer gratings are in non-overlapping regions of the sample, wherein the first and second-layer gratings have a common pitch, wherein a corresponding one of the one or more optical metrology measurements is based on a relative imaged shift between the first and second-layer gratings.

7. The optical metrology system of claim 6, wherein the optical metrology target comprises:
an advanced imaging metrology (AIM) target.

8. The optical metrology system of claim 6, wherein the single non-zero diffraction order of light from each of the mutually-coherent illumination beams comprises:
first-order diffraction from each of the mutually-coherent illumination beams.

9. The optical metrology system of claim 1, wherein the one or more sets of periodic features on the optical metrology target comprise:
a first Moiré structure comprising:
a first-layer grating with a first pitch on a first layer of the sample; and
a second-layer grating with a second pitch on a second layer of the sample, wherein the first and second-layer gratings are formed in a first overlapping region of the sample; and
a second Moiré structure comprising:
a third grating with the second pitch on the first layer of the sample; and
a fourth grating with the first pitch on the second layer of the sample, wherein the third and fourth gratings are formed in a second overlapping region of the sample.

10. The optical metrology system of claim 9, wherein the optical metrology target comprises:
a robust advanced imaging metrology (r-AIM) target.

11. The optical metrology system of claim 9, wherein the single non-zero diffraction order of light from each of the mutually-coherent illumination beams comprises:
a Moiré diffraction order of light from each of the mutually-coherent illumination beams associated with sequential diffraction from the first-layer grating and the second-layer grating.

12. The optical metrology system of claim 1, wherein a number of the one or more pairs of the mutually-coherent illumination beams is equal to a number of the one or more sets of periodic features in accordance with the metrology recipe.

13. The optical metrology system of claim 1, wherein illumination beams in a respective one of the one or more pairs of the mutually-coherent illumination beams are directed to the optical metrology target simultaneously.

14. The optical metrology system of claim 1, wherein the illumination beams in a respective one of the one or more pairs of the mutually-coherent illumination beams are directed to the optical metrology target sequentially.

15. The optical metrology system of claim 1, wherein the optical metrology target has outer dimensions smaller than 20 micrometers.

16. The optical metrology system of claim 1, wherein the optical metrology target has outer dimensions smaller than 8 micrometers.

17. The optical metrology system of claim 1, wherein the one or more optical metrology measurements comprise:
overlay measurements.

18. The optical metrology system of claim 1, wherein the one or more optical metrology measurements comprise:
scanner alignment measurements.

19. An optical metrology method, comprising:
directing one or more pairs of mutually-coherent illumination beams to an optical metrology target on a sample, wherein the optical metrology target includes one or more sets of periodic features associated with two or more different lithographic exposures, wherein the one or more sets of periodic features have periodicity along one or more measurement directions, wherein the illumination beams in a respective pair of the mutually-coherent illumination beams are directed to the sample with opposing azimuth incidence angles and a common altitude incidence angle, wherein the azimuth incidence angles of the one or more pairs of the mutually-coherent illumination beams are azimuthally rotated with respect to the one or more measurement directions;
generating one or more images of the optical metrology target with a detector, wherein the one or more images are dark-field images, wherein an image of a particular one of the one or more sets of periodic features includes a sinusoidal interference pattern generated by interference of a single non-zero diffraction order of light from each of the illumination beams within a particular pair of the one or more pairs of the mutually-coherent illumination beams; and
generating one or more optical metrology measurements along the one or more measurement directions based on the one or more images of the optical metrology target received from the detector.

20. The optical metrology method of claim 19, further comprising:
collecting at least some zero-order side lobes from the one or more pairs of the mutually-coherent illumination beams; and
preventing, with one or more blockers at least some of the zero-order side lobes from reaching the detector.

21. The optical metrology method of claim 20, wherein the one or more blockers are located in opposing quadrants of a pupil plane of an imaging sub-system including the detector.

22. The optical metrology method of claim 19, further comprising:
collecting at least some zero-order side lobes from the one or more pairs of the mutually-coherent illumination beams; and
generating the one or more optical metrology measurements by:
filtering one or more signals associated with interference between the zero-order side lobes and any of the non-zero diffraction orders from the one or more images to generate one or more filtered images; and
generating the one or more optical metrology measurements based on the one or more filtered images.

23. The optical metrology method of claim 22, wherein the one or more signals in the one or more images associated with interference between the zero-order side lobes and any of the non-zero diffraction orders include interference fringes along a different direction than interference between the non-zero diffraction orders, wherein filtering the one or more signals comprises filtering the one or more signals based on fringe direction.

24. The optical metrology method of claim 19, wherein the one or more sets of periodic features on the optical metrology target comprise:
a first-layer grating on a first layer of the sample; and
a second-layer grating on a second layer of the sample, wherein the first and second-layer gratings are in non-overlapping regions of the sample, wherein the first and second-layer gratings have a common pitch, wherein a corresponding one of the one or more optical metrology measurements is based on a relative shift between the first and second-layer gratings in the one or more images.

25. The optical metrology method of claim 24, wherein the optical metrology target comprises:
an advanced imaging metrology (AIM) target.

26. The optical metrology method of claim 24, wherein the single non-zero diffraction order of light from each of the mutually-coherent illumination beams comprises:
first-order diffraction from each of the mutually-coherent illumination beams.

27. The optical metrology method of claim 19, wherein the one or more sets of periodic features on the optical metrology target comprise:
a first Moiré structure comprising:
a first-layer grating with a first pitch on a first layer of the sample; and
a second-layer grating with a second pitch on a second layer of the sample, wherein the first and second-layer gratings are formed in a first overlapping region of the sample; and
a second Moiré structure comprising:
a third grating with the second pitch on the first layer of the sample; and
a fourth grating with the first pitch on the second layer of the sample, wherein the third and fourth gratings are formed in a second overlapping region of the sample.

28. The optical metrology method of claim 27, wherein the optical metrology target comprises:
a robust advanced imaging metrology (r-AIM) target.

29. The optical metrology method of claim 27, wherein the single non-zero diffraction order of light from each of the mutually-coherent illumination beams comprises:
a Moiré diffraction order of light from each of the mutually-coherent illumination beams associated with sequential diffraction from the first-layer grating and the second-layer grating.

30. The optical metrology method of claim 19, wherein a number of the one or more pairs of the mutually-coherent illumination beams is equal to a number of the one or more sets of periodic features.

31. The optical metrology method of claim 19, wherein illumination beams in a respective one of the one or more pairs of the mutually-coherent illumination beams are directed to the optical metrology target simultaneously.

32. The optical metrology method of claim 19, wherein illumination beams in a respective one of the one or more pairs of the mutually-coherent illumination beams are directed to the optical metrology target sequentially.

33. The optical metrology method of claim 19, wherein the optical metrology target has outer dimensions smaller than 20 micrometers.

34. The optical metrology method of claim 19, wherein the optical metrology target has outer dimensions smaller than 8 micrometers.

35. The optical metrology method of claim 19, wherein the one or more optical metrology measurements comprise:
overlay measurements.

36. The optical metrology method of claim 19, wherein the one or more optical metrology measurements comprise:
scanner alignment measurements.

37. An optical metrology system, comprising:
a controller including one or more processors configured to execute program instructions causing the one or more processors to implement a metrology recipe by:
generating one or more optical metrology measurements along one or more measurement directions based on one or more images of an optical metrology target, wherein the optical metrology target includes one or more sets of periodic features associated with two or more different lithographic exposures, wherein the one or more sets of periodic features have periodicity along the one or more measurement directions, wherein the one or more images are generated by:
directing one or more pairs of mutually-coherent illumination beams to the optical metrology target on a sample, wherein the illumination beams in a respective pair of the mutually-coherent illumination beams are directed to the sample with opposing azimuth incidence angles and a common altitude incidence angle, wherein the opposing azimuth incidence angles of the one or more pairs of the mutually-coherent illumination beams are azimuthally rotated with respect to the one or more measurement directions, wherein an image of a particular one of the one or more sets of periodic features includes a sinusoidal interference pattern generated by interference of a single non-zero diffraction order of light from each of the illumination beams within a particular pair of the one or more pairs of the mutually-coherent illumination beams;
filtering one or more signals associated with interference between collected zero-order side lobes and any of the non-zero diffraction orders from the one or more images to generate one or more filtered images; and
generating the one or more optical metrology measurements based on the one or more filtered images.
